(19) United States
(12) Patent Application Publication
(10) Pub. No.: US 2016/0314996 A1
(43) Pub. Date: Oct. 27, 2016

(54) SUBSTRATE TREATING APPARATUS AND A METHOD FOR TREATING A SUBSTRATE

(71) Applicant: Samsung Electronics Co., Ltd., Suwon-si (KR)

(72) Inventors: IL HWAN KIM, Hwaseong-si (KR); Sang Hyun BAE, Seoul (KR); HYUEKJAE LEE, Hwaseong-si (KR); Taeje CHO, Yongin-si (KR); Kwang-chul CHOI, Suwon-si (KR)

(21) Appl. No.: 15/099,926

(22) Filed: Apr. 15, 2016

(30) Foreign Application Priority Data
Apr. 21, 2015 (KR) 10-2015-0056039

(51) Int. Cl. H01L 21/67; H01L 21/687

(52) U.S. Cl. CPC H01L 21/67092; H01L 21/68771; H01L 21/67051; H01L 21/68764

(57) ABSTRACT

The inventive concepts relate to a substrate treating apparatus and a method for treating a substrate using the same. The apparatus includes a spin chuck configured to support a substrate, a grinding head disposed over the spin chuck and configured to grind the substrate supported by the spin chuck, and a nozzle member including a jet nozzle configured to jet high-pressure water to the substrate supported by the spin chuck. The jet nozzle overlaps with the substrate to jet the high-pressure water to an edge of the substrate.

### CROSS-REFERENCE TO RELATED APPLICATION

This U.S. non-provisional patent application claims priority under 35 U.S.C. §119 to Korean Patent Application No. 10-2015-0056039, filed on Apr. 21, 2015, in the Korean Intellectual Property Office, the disclosure of which is hereby incorporated by reference in its entirety.

### FIELD OF INVENTION

Embodiments of the inventive concepts relate to a substrate treating apparatus and a method for treating a substrate using the same. More particularly, embodiments of the inventive concepts relate to an apparatus for treating a back side of a substrate and a method for treating a substrate using the same.

### BACKGROUND

As current technology develops, high-performance, high-speed and smaller electronic components are in high demand. To satisfy these demands, miniaturization of semiconductor chips has become a top priority. One method used to achieve this is reducing the thickness of semiconductor wafers used in the manufacture of semiconductor chips. The thickness of a wafer may be reduced by a back grinding process as part of the semiconductor manufacturing process in which, the wafer is adhered to a carrier by an adhesive.

### SUMMARY

Embodiments of the inventive concepts may provide a substrate treating apparatus and method that are capable of reducing process defects.

In one aspect, a substrate treating apparatus may include a spin chuck configured to support a substrate, a grinding head disposed over the spin chuck and configured to grind the substrate supported by the spin chuck, and a nozzle member including a jet nozzle configured to jet high-pressure water to the substrate supported by the spin chuck. The jet nozzle may overlap with the substrate to jet the high-pressure water to an edge of the substrate.

In an embodiment, the high-pressure water may be jetted in a direction from a center of the substrate toward the edge of the substrate when viewed from a plan view, and the high-pressure water may be jetted at an angle inclined to a top surface of the spin chuck when viewed from a cross-sectional view.

In an embodiment, the jet nozzle may jet the high-pressure water by a water jet method.

In an embodiment, a jet pressure of the high-pressure water may be in a range of 100 bar to 800 bar.

In an embodiment, the nozzle member may further include a support shaft disposed adjacently to the spin chuck, an arm connected to the support shaft and extending over the substrate, and a nozzle body coupled to the arm to overlap with the substrate. The jet nozzle may be combined with the nozzle body.

In an embodiment, the nozzle body may be configured to be linearly movable along the arm in a longitudinal direction of the arm, and the nozzle body may also be configured to be rotatable in a vertical plane on a rotation shaft that is perpendicular to the longitudinal direction.

In an embodiment, the arm may be configured to be vertically movable along a longitudinal direction of the support shaft.

In an embodiment, the apparatus may include a plurality of jet nozzles.

In an embodiment, the grinding head may be a diamond wheel, or a grinding head for polishing.

In an embodiment, the substrate treating apparatus may further include an index table on which the spin chuck is installed. The spin chuck may include a plurality of spin chucks including first, second, third and fourth spin chucks installed on the index table at 90 degree intervals, and the grinding head may include a plurality of grinding heads respectively disposed over the second, third and fourth spin chucks.

In an embodiment, the grinding head disposed over the second spin chuck may include a grinding head configured to perform a rough grinding process of roughly grinding a substrate disposed thereunder. The grinding head disposed over the third spin chuck may include a grinding head configured to perform a finishing process of finely grinding a substrate disposed thereunder. The grinding head disposed over the fourth spin chuck may include a grinding head configured to perform a polishing process of planarizing a substrate disposed thereunder. The nozzle member may be provided adjacently to one of the second to fourth spin chucks to jet the high-pressure water to a substrate supported by the one spin chuck.

In an embodiment, the nozzle member may be provided adjacently to the second spin chuck.

In an embodiment, the nozzle member may include a plurality of nozzle members provided adjacently to the second to fourth spin chucks, respectively.

In another aspect, a method for treating a substrate may include loading a substrate coupled to a carrier by an adhesive layer onto a spin chuck, performing a grinding process to thin the substrate and to expose the adhesive layer disposed on a sidewall of the substrate thinned by the grinding process, and jetting high-pressure water to the exposed adhesive layer to remove at least a portion of the exposed adhesive layer. The high-pressure water may be jetted in a direction from a center of the substrate toward an edge of the substrate when viewed from a plan view, and the high-pressure water may be jetted at a jet angle inclined to a top surface of the spin chuck when viewed from a cross-sectional view.

In an embodiment, the high-pressure water may be jetted by a water-jet method.

In an embodiment, a jet pressure of the high-pressure water may be in a range of 100 bar to 800 bar.

In an embodiment, the jet angle of the high-pressure water may be in a range of 45 degrees to 60 degrees.

In an embodiment, the substrate may include a device portion and an edge portion surrounding the device portion. The device portion may protrude from the edge portion toward the carrier by a first thickness. The adhesive layer may include a first portion disposed between the device portion and the carrier and a second portion disposed between the edge portion and the carrier. The second portion may be removed by the grinding process, and the exposed adhesive layer may correspond to the second portion of the adhesive layer.

In an embodiment, an outer sidewall of the second portion may have a profile curved toward the first portion.

In an embodiment, performing the grinding process may include performing a rough grinding process of roughly grinding the substrate, performing a finishing process of finely grinding the roughly ground substrate, and performing a polishing process of planarizing the finely ground substrate. The edge portion may be removed by the rough grinding process, and the high-pressure water may be jetted as part of the rough grinding process.

In an embodiment, performing the rough grinding process may include performing a first rough grinding process and a second rough grinding process. The device portion may be thinned to have a second thickness less than the first thickness by the first rough grinding process, the device portion may be thinned to have a third thickness less than the second thickness by the second rough grinding process, and the high-pressure water may be jetted after the first rough grinding process.

In an embodiment, jetting the high-pressure water may be performed simultaneously with the second rough grinding process.

In an embodiment, the substrate may include a through-via, and a bottom surface of the through-via may be exposed by the polishing process.

In an embodiment, the grinding process and jetting the high-pressure water may be performed in the same apparatus.

In an embodiment, a release layer may be additionally disposed between the substrate and the adhesive layer to couple the substrate to the carrier.

### BRIEF DESCRIPTION OF THE DRAWINGS

Exemplary embodiments of one or more new and useful process, machine, manufacture, and/or improvement thereof, in accordance with the inventive concept, are provided in the following detailed description taken in conjunction with the accompanying drawings, in which:

FIG. 1 is a schematic plan view diagram illustrating a substrate treating apparatus according to aspects of the present inventive concepts.

FIG. 2 is a schematic side view diagram illustrating the substrate treating apparatus of FIG. 1.

FIG. 3 is a perspective view diagram illustrating an end portion of a nozzle member according to aspects of the present inventive concepts.

FIG. 4 is a schematic side view diagram illustrating a state where high-pressure water is jetted from a nozzle member to a substrate according to aspects of the present inventive concepts.

FIG. 5A is a perspective view diagram illustrating a substrate treating apparatus according to aspects of the present inventive concepts.

FIG. 5B is a plan view diagram illustrating a modified embodiment of the substrate treating apparatus of FIG. 5A.

FIGS. 6, 9, 10, 12 to 14, and 17 to 20 are schematic side view diagrams illustrating a method for manufacturing a semiconductor device, according to aspects of the inventive concepts.

FIG. 7 is an enlarged view diagram of a portion ‘A’ of FIG. 6.

FIG. 8 is a flow chart illustrating a method for treating a substrate, according to aspects of the inventive concepts.

FIG. 11 is an enlarged view diagram of a portion ‘B’ of FIG. 10.

FIGS. 15 and 16 are enlarged view diagrams of a portion ‘A’ of FIG. 14.

FIG. 21 is a schematic block diagram illustrating an example of a package module including a semiconductor device manufactured according to aspects of the inventive concepts.

FIG. 22 is a schematic block diagram illustrating an example of an electronic device including a semiconductor device manufactured according to aspects of the inventive concepts.

FIG. 23 is a schematic block diagram illustrating an example of a memory system including a semiconductor device manufactured according to aspects of the inventive concepts.

### DETAILED DESCRIPTION OF THE EMBODIMENTS

Aspects of the inventive concept will now be described more fully with reference to the accompanying drawings, in which exemplary embodiments are shown. The inventive concept may, however, be embodied in many different forms and should not be construed as limited to the exemplary embodiments set forth herein. Reference numerals are denoted in detail in the exemplary embodiments of the inventive concept and their examples are indicated in the accompanying drawings. The same reference numerals are used in the description and drawings in order to refer to the same or similar parts wherever possible.

It will be understood that, although the terms first, second, etc. are be used herein to describe various elements, these elements should not be limited by these terms. These terms are used to distinguish one element from another, but not to imply a required sequence of elements. For example, a first element can be termed a second element, and, similarly, a second element can be termed a first element, without departing from the scope of the present invention. As used herein, the term “and/or” includes any and all combinations of one or more of the associated listed items.

It will be understood that when an element is referred to as being “on” or “connected” or “coupled” to another element, it can be directly on or connected or coupled to the other element or intervening elements can be present. In contrast, when an element is referred to as being “directly on” or “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements, and/or components, but do not preclude the presence or addition of one or more other features, steps, operations, elements, components, and/or groups thereof.

Spatially relative terms, such as “beneath,” “below,” “lower,” “above,” “upper” and the like may be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as “below” and/or “beneath” other elements or features would then be oriented “above” the other elements or features. The device may be otherwise oriented (e.g., rotated 90 degrees or at other orientations) and the spatially relative descriptors used herein interpreted accordingly.

To the extent that functional features, operations, and/or steps are described herein, or otherwise understood to be included within various embodiments of the inventive concept, such functional features, operations, and/or steps can be embodied in functional blocks, units, modules, operations and/or methods. And to the extent that such functional blocks, units, modules, operations and/or methods include computer program code, such computer program code can be stored in a computer readable medium, e.g., such as non-transitory memory and media, that is executable by at least one computer processor.

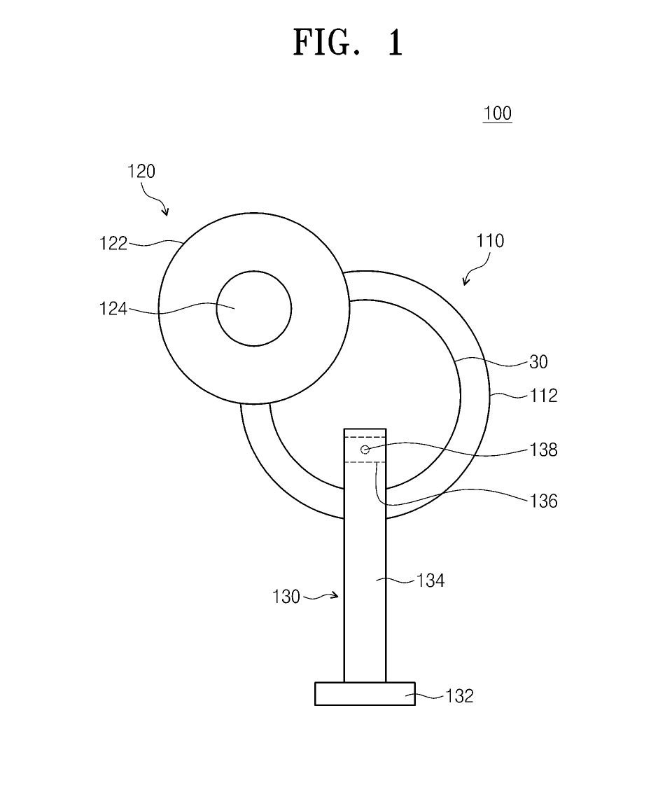

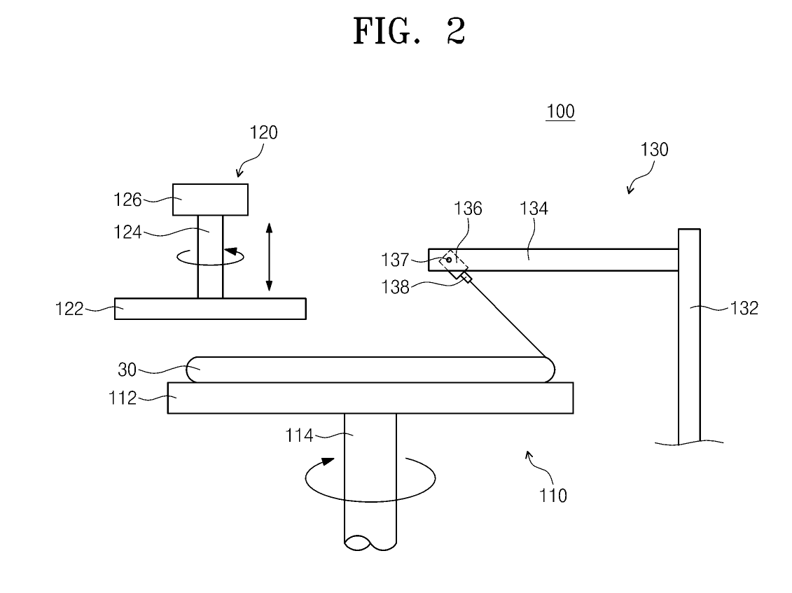

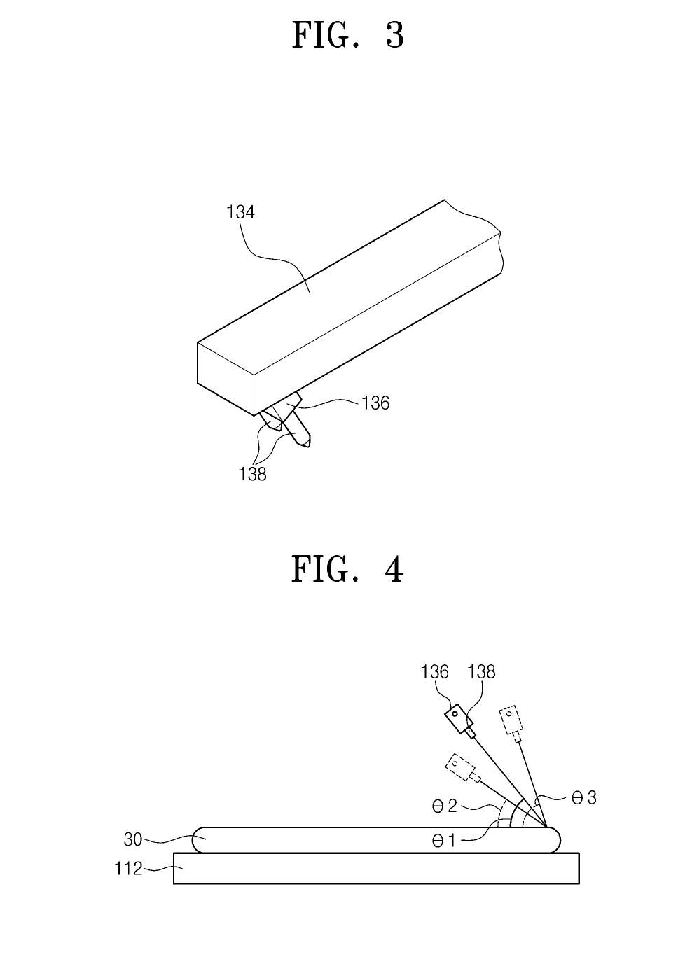

FIG. 1 is a schematic plan view diagram illustrating a substrate treating apparatus according to aspects of the inventive concepts. FIG. 2 is a schematic side view diagram illustrating the substrate treating apparatus of FIG. 1. FIG. 3 is a perspective view diagram illustrating an end portion of a nozzle member.

Referring to FIGS. 1 and 2, a substrate treating apparatus 100 includes a support member 110 for supporting and rotating a substrate 30, a grinding member 120 for grinding the substrate 30, and a nozzle member 130 for jetting high-pressure water to a top surface of the substrate 30.

The support member 110 includes a spin chuck 112 supporting the substrate 30, and a first rotation unit 114 connected to a bottom surface of the spin chuck 112. The first rotation unit 114 transmits a rotational force generated from a first driving part (not shown) to the spin chuck 112. The substrate 30 supported by the spin chuck 112 may be fixed to the spin chuck 112 by an electrostatic force or a vacuum and is rotated by the rotation of the spin chuck 112. A motor may be used as the first driving part (not shown). A size (e.g., a diameter) of the spin chuck 112 may be greater than that of the substrate 30. Alternatively to FIGS. 1 and 2, the substrate 30 may be combined with a carrier by an adhesive layer and then may be safely loaded on the spin chuck 112 to face a grinding head 122. This will be described later in more detail.

The grinding member 120 includes the grinding head 122 for grinding the substrate 30, a spindle 124 connected to the grinding head 122 to drive the grinding head 122, and a second driving part 126 providing a driving force to the spindle 124.

The grinding head 122 may be disposed over the spin chuck 112 so as to partially overlap with the substrate 30. According to an aspect of the inventive concept, the grinding head 122 may be a diamond wheel. In this embodiment, the grinding head 122 may include a nickel plate to which diamond particles are adhered. The grinding head 122, including the nickel plate, is rotated and comes into contact with a back side of the substrate 30 to grind the back side of the substrate 30. According to another aspect of the inventive concept, the grinding head 122 may be a grinding head for polishing and may alternatively include a cotton flannel or paper member, which is smooth or fine. In such embodiments, the grinding head used for polishing may not necessarily perform the grinding function by itself, unlike the diamond wheel, but may have the grinding function performed by means of slurry additionally supplied between the grinding head and the substrate. The spindle 124 rotates the grinding head 122 and vertically adjusts the height of the grinding head 122 relative to the substrate 30 to pressure the back side of the substrate 30. In other words, the grinding head 122 is vertically moved by the spindle 124 to come in contact with the substrate 30 and is rotated by the spindle 124 to grind the substrate 30. During the grinding process, the substrate 30 may be independently rotated by the rotation of the spin chuck 112 by the first rotation unit 114.

The nozzle member 130 includes a support shaft 132 provided to be adjacent to the spin chuck 112, an arm 134 connected to the support shaft 132 and extending over the substrate 30, and a nozzle body 136 connected to the arm 134 and overlapping with the substrate 30.

The support shaft 132 may be disposed on a housing (not shown) on which the support member 110 is installed. However, embodiments of the inventive concepts are not limited thereto. The support shaft 132 is connected to one end of the arm 134 to support the arm 134. The arm 134 may be configured to vertically move along the support shaft 132. In an embodiment, a first guide rail (not shown) extending in a longitudinal direction of the support shaft 132 may be provided to the support shaft 132, and the arm 134 may be configured to vertically move along the first guide rail (not shown). In an embodiment, the support shaft 132 may be connected to a third driving part (not shown), and the third driving part (not shown) may elevate or vertically move the support shaft 132 and the arm 134. The nozzle body 136 may vertically move relative to the substrate 30 by the vertical movement of the arm 134 or of the support shaft 132.

A jet nozzle 138 is combined with the nozzle body 136. The jet nozzle 138 may be a water jet nozzle that jets high-pressure water by a water-jet method. For example, a jet pressure of the high-pressure water output by jet nozzle 138 may be in a range of 100 bar to 800 bar. A single jet nozzle 138 is combined with the nozzle body 136 in FIGS. 1 and 2. However, embodiments of the inventive concepts are not limited thereto. In an embodiment, the jet nozzle 138 may be provided in plurality, as illustrated in FIG. 3. A supply pipe (not shown) for supplying the high-pressure water pressurized by a pump (not shown) may be connected to the nozzle body 136. In an embodiment, the supply pipe may be provided within the arm 134. However, embodiments of the inventive concepts are not limited thereto.

The nozzle body 136 may be configured to linearly move along a longitudinal direction of the arm 134. In an embodiment, a second guide rail (not shown) extending in the longitudinal direction of the arm 134 may be provided to the arm 134, and the nozzle body 136 may linearly move along the second guide rail (not shown) to be controlled to be disposed at different positions over the substrate 30. In addition, the nozzle body 136 may be configured to be rotated on a rotation shaft 137 intersecting the longitudinal direction of the arm 134. Accordingly, the nozzle body 136 and the jet nozzle 138 are capable of being be rotated about shaft 137, linearly moved along arm 134 and vertically moved along support shaft 132.

FIG. 4 is a cross-sectional view illustrating a state where high-pressure water is jetted from the nozzle body 136 and the jet nozzle 138 to the substrate 30.

Referring to FIGS. 1, 2, and 4, the jet nozzle 138 may be controlled to jet the high-pressure water toward an edge of the substrate 30. The high-pressure water may be jetted by the jet nozzle 138 at a predetermined angle θ1 inclined to a top surface of the substrate 30 in a direction outwardly from a center portion of the substrate 30 toward the edge of the substrate 30. The jet angle θ1 of the high-pressure water jetted toward the edge of the substrate 30 may be controlled by the linear movement, the vertical movement and the rotation of the jet nozzle 138, as described above. In an embodiment, if the jet nozzle 138 is moved downward, toward the substrate 30, at the same horizontal position relative to the arm 134, a jet angle θ2 of the high-pressure water jetted to the edge of the substrate 30 will be less than the jet angle θ1. In an embodiment, if the jet nozzle 138 linearly moves along arm 134 at the same vertical position relative to the substrate 30 to come closer to the edge of the substrate 30, a jet angle θ3 of the high-pressure water jetted to the edge of the substrate 30 will be greater than the jet angle θ1. Multiple directional components (i.e., an x-directional component and a y-directional component) of physical force applied to the edge of the substrate 30 by the high-pressure water may be varied according to the jet angle and vertical and horizontal position of the high-pressure water.

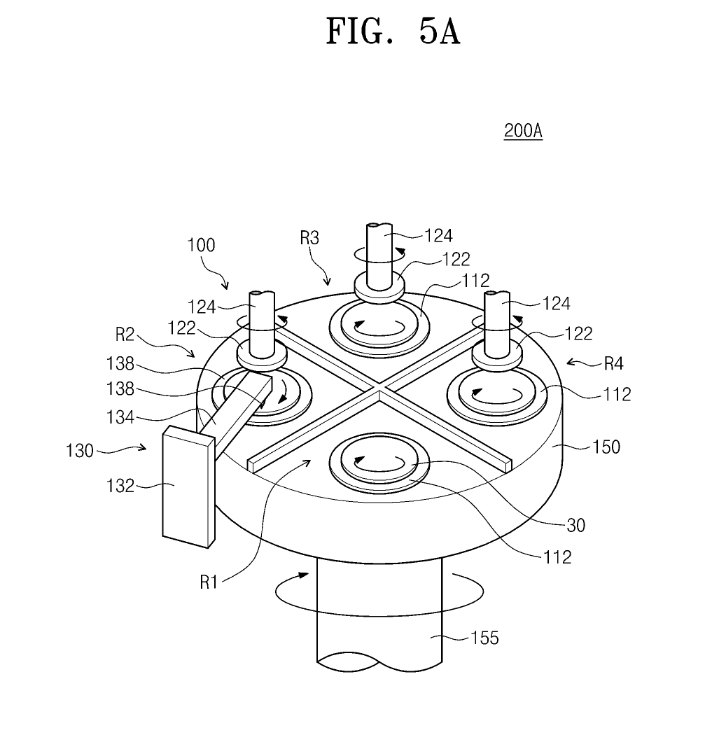

FIG. 5A is a perspective view illustrating a substrate treating apparatus 200A according to aspects of the inventive concepts. FIG. 5B is a plan view illustrating a modified embodiment 200B of the substrate treating apparatus of FIG. 5A. A substrate treating apparatus 200A of FIG. 5A may include at least one substrate treating apparatus 100 of FIG. 1.

Referring to FIG. 5A, the substrate treating apparatus 200A includes a loading region R1, a first grinding region R2, a second grinding region R3, and a polishing region R4. A spin chuck 112 is provided in each of the regions R1 to R4, and grinding heads 122 connected to spindles 124 is provided over the spin chucks 112 of the first and second grinding regions R2 and R3 and polishing region R4. A nozzle member 130 is provided to be adjacent to the first grinding region R2, in the position of apparatus 200A in FIG. 5A. The nozzle member 130 jets high-pressure water to a substrate 30 safely loaded on the spin chuck 112 of the first grinding region R2. In the present embodiment, the nozzle member 130 is provided to be adjacent to the first grinding region R2. However, embodiments of the inventive concepts are not limited thereto. In an alternative embodiment, the nozzle member 130 may be adjacent to the second grinding region R3 or the polishing region R4 so as to jet the high-pressure water to a substrate 30 safely loaded on the spin chuck 112 of the second grinding region R3 or the polishing region R4. In an embodiment, the nozzle member 130 may be provided in plurality, as illustrated in FIG. 5B. In other words, a substrate treating apparatus 200B of FIG. 5B includes a plurality of nozzle members 130. The plurality of nozzle members 130 is provided to be adjacent to the first and second grinding regions R2 and R3 and the polishing region R4 to jet high-pressure water to substrates 30 safely loaded on the spin chucks 112 of the regions R2, R3 and R4, respectively.

The spin chucks 112 may be installed on an index table 150. The index table 150 may have a cylindrical shape and may be divided into sub-regions at substantially 90 degree intervals. The sub-regions of the index table 150 correspond to the regions R1 to R4, respectively. A second rotation unit 155 may be connected to a bottom surface of the index table 150. The second rotation unit 155 rotates the index table 150 at about 90 degree intervals in one direction as a process is performed. The spin chucks 112 may be rotated independently of each other, and the grinding heads 122 may also be rotated independently of each other.

Other elements of the substrate treating apparatuses 200A and 200B may be substantially the same as or similar to corresponding elements described with reference to FIGS. 1 to 4, so the descriptions to the other elements are omitted for the purpose of ease and convenience in explanation.

The loading region R1 may be a region for substantially starting the substrate treating process. A substrate 30, on which previous processes may have been performed, is loaded on loading region R1 of the substrate treating apparatus 200A so as to be safely loaded on the spin chuck 112 of the loading region R1.

The first grinding region R2 may be a rough grinding process region for roughly grinding a back side of the substrate 30. When the substrate 30 loaded on the spin chuck 112 of the loading region R1 is moved into the first grinding region R2 by the rotation of the index table 150, the rough grinding process associated with first grinding region R2 is performed on the substrate 30. The grinding head 122 of the first grinding region R2 may be formed of, for example, a 350 mesh diamond wheel to perform the rough grinding process. However, it will be understood that the abrasion level of the grinding head can vary and is not pertinent to the present inventive concepts. The nozzle member 130 may jet the high-pressure water toward the edge of the substrate 30 during the rough grinding process. As described in detail below, if the substrate 30 coupled to a carrier with an adhesive layer is provided, the high-pressure water may be jetted to remove a portion of the adhesive layer exposed by the rough grinding process. In other words, the substrate treating apparatus 200A may be a back grinding apparatus which grinds the back side of the substrate 30 combined with the carrier through the adhesive layer so as to reduce the thickness of the substrate 30 and jets the high-pressure water to the back side of the reduced-thickness substrate 30 to remove the portion of the adhesive layer exposed by the grinding process.

The second grinding region R3 may be a finishing process region for finely grinding the roughly ground back side of the substrate 30. If the substrate 30 is moved into the second grinding region R3 after the rough grinding process is completed, the finishing process may be performed on the substrate 30. The grinding head 122 of the second grinding region R3 may be formed of, for example, a 2000 mesh diamond wheel to perform the fine-grinding finishing process.

The polishing region R4 may be a polishing process region for planarizing the finely ground back side of the substrate 30. If the substrate 30 is moved into the polishing region R4 after the finishing process is completed in region R3, the polishing process may be performed on the substrate 30. The grinding head 122 of the polishing region R4 may be formed of a grinding head for polishing to perform the polishing process. The grinding head for polishing may have a cotton flannel or paper member, which is smooth or fine. In other words, the grinding head for polishing may not necessarily provide the grinding function by itself, unlike the diamond wheels of region R2 and region R3, but may have a grinding function by means of slurry additionally supplied to the substrate 30 and polished by the grinding head 122 of the polishing region R4.

A method for manufacturing a semiconductor device (or a semiconductor package) using the substrate treating apparatus 200A will be described hereinafter. The method for manufacturing the semiconductor device may include a method for treating a substrate using the substrate treating apparatus 200A. This will also be described.

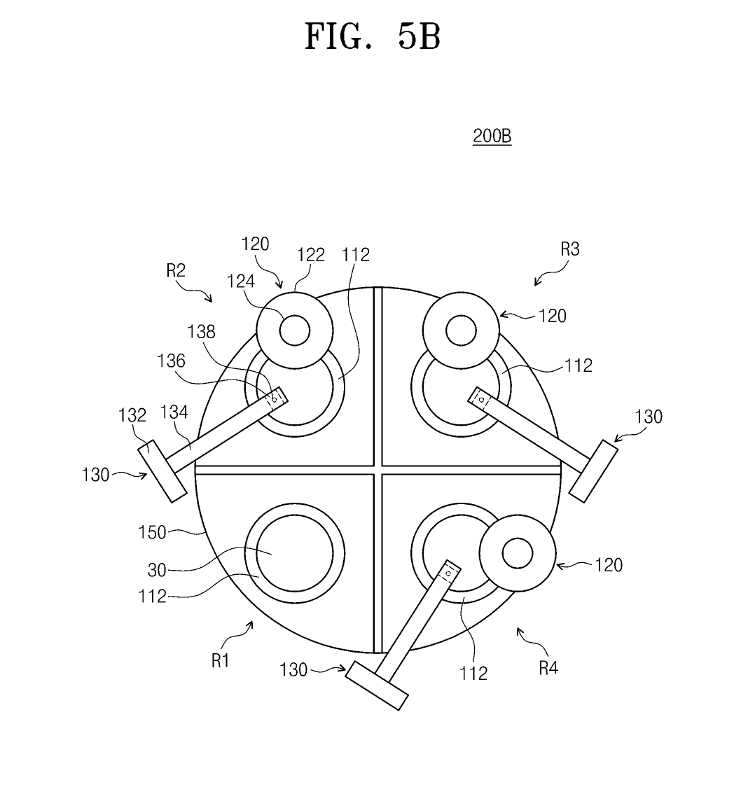

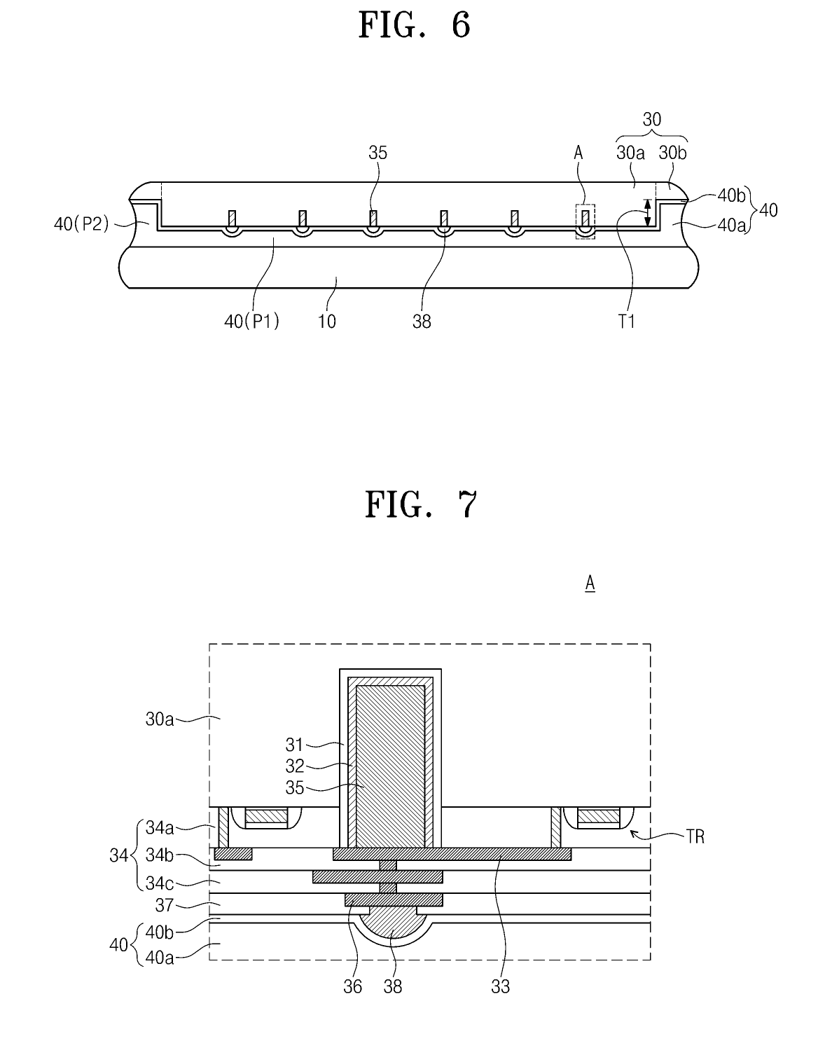

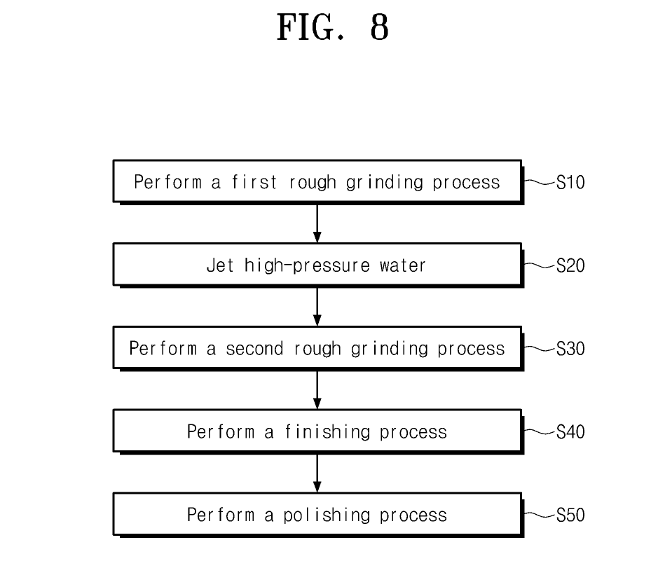

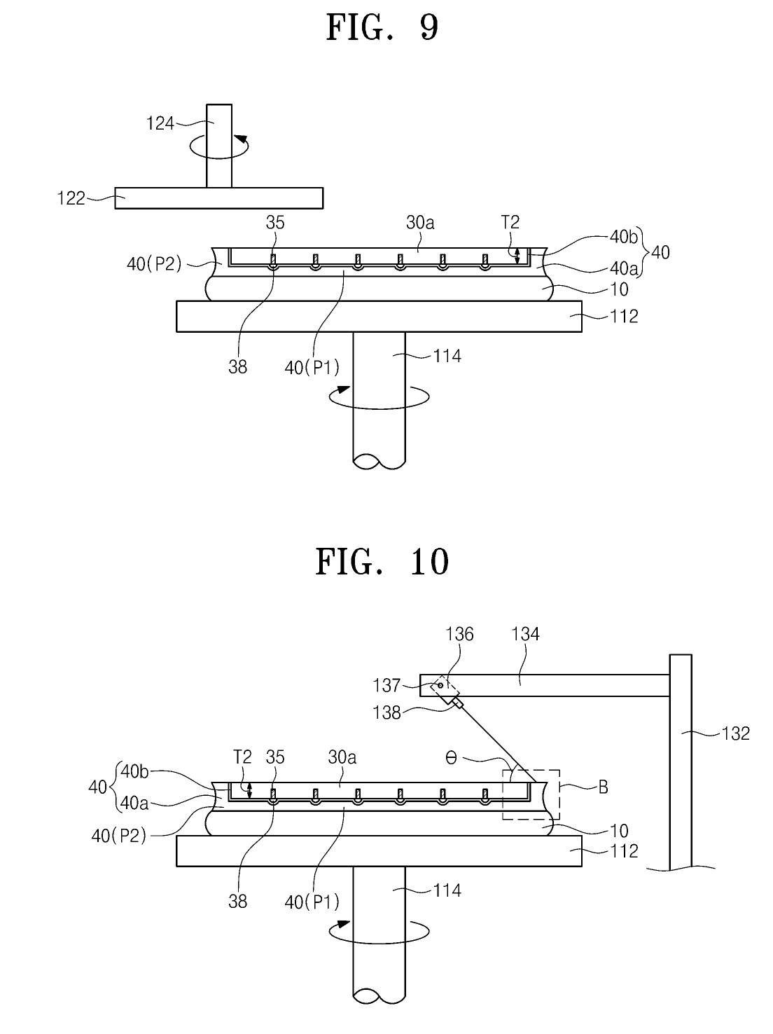

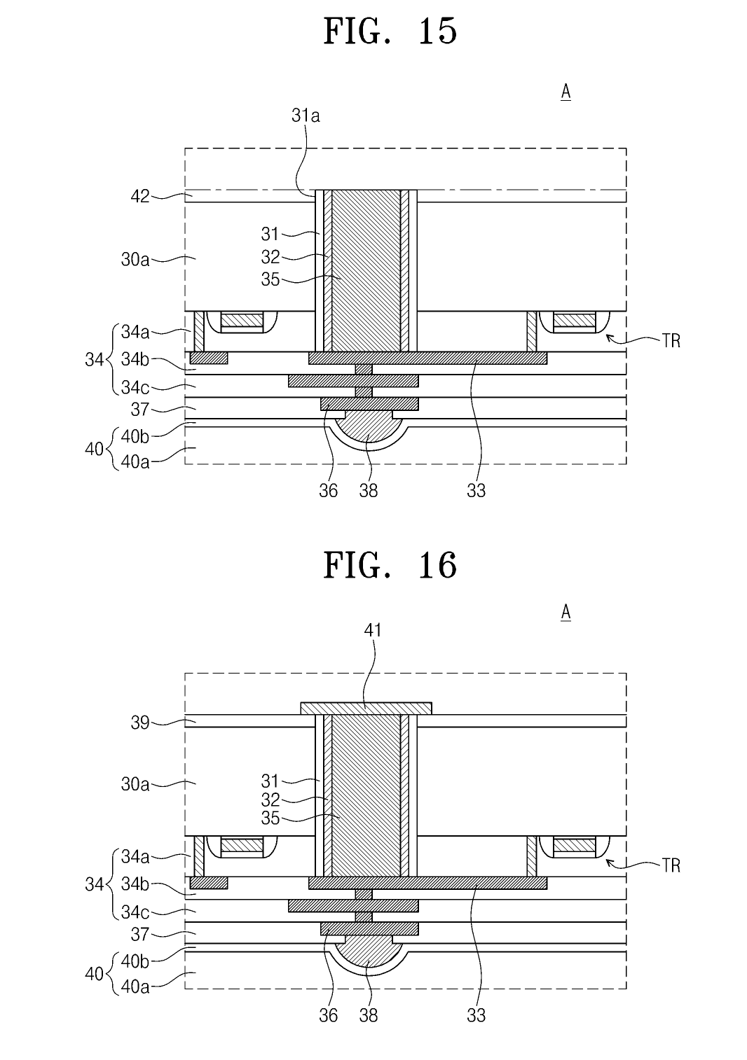

FIGS. 6, 9, 10, 12 to 14, and 17 to 20 are cross-sectional views illustrating a substrate mounted on a carrier (FIGS. 6, and 17-20) in various stages of the process and various portions of the substrate treating apparatus 100, along with a substrate mounted on a carrier (FIGS. 9, 10 and 12-14) in various stages of the process to illustrate a method for manufacturing a semiconductor device, according to an embodiment of the inventive concepts. FIG. 7 is an enlarged view of a portion ‘A’ of FIG. 6. FIG. 8 is a flow chart illustrating a method for treating a substrate, according to aspects of the inventive concepts. FIG. 11 is an enlarged view of a portion ‘B’ of FIG. 10. FIGS. 15 and 16 are enlarged views of a portion ‘A’ of FIG. 14.

Referring to FIG. 6, a substrate 30 and a carrier 10 are shown. The substrate 30 may be a substrate including a semiconductor material such as silicon. The substrate 30 may be a silicon wafer used in the present embodiment. In an embodiment, the substrate 30 may be a silicon wafer on which a front end of line (FEOL) process is performed. The substrate 30 may include a device portion 30a and an edge portion 30b. The device portion 30a may be used as a semiconductor chip after a subsequent cutting process. Hereinafter, the device portion 30a may be called a device portion substrate 30a′. FIG. 7 is an enlarged view of a portion ‘A’ of the device portion 30a.

Referring to FIG. 7, transistors TR are disposed on the device portion substrate 30a. The transistors TR are covered with interlayer insulating layers 34. Interconnections 33 are disposed in the interlayer insulating layers 34. A through-via 35 penetrates a first interlayer insulating layer 34a and a portion of the device portion substrate 30a so as to be in contact with the interconnection 33 disposed in a second interlayer insulating layer 34b. The through-via 35 may be formed of a metal (e.g., copper). A diffusion preventing layer 32 and an insulating layer 31 are conformally disposed between the through-via 35 and the device portion substrate 30a and between the through-via 35 and the first interlayer insulating layer 34a. A first conductive pad 36 is disposed on a third interlayer insulating layer 34c. A portion of the first conductive pad 36 and the third interlayer insulating layer 34c is covered with a first passivation layer 37. A conductive bump 38 penetrates the first passivation layer 37 so as to be in contact with the first conductive pad 36.

Referring again to FIG. 6, the carrier 10 may be coupled or bonded to the substrate 30 in such a way that the carrier 10 faces the conductive bumps 38. The carrier 10 is provided to support the substrate 30. In an embodiment, the carrier 10 supports the substrate 30 during a back grinding process recessing a back side of the substrate 30, thereby preventing the substrate 30 from being bent or otherwise damaged. Here, the back side of the substrate 30 may be opposite to a front side of the substrate 30, on which the conductive bumps 38 are provided. An adhesive layer 40a may be provided between the substrate 30 and the carrier 10 to firmly bond the substrate 30 to the carrier 10. The adhesive layer 40a may include a thermosetting adhesive capable of being hardened by heat, or an ultraviolet (UV) curing adhesive capable of being hardened by light (e.g., UV). For example, the thermosetting adhesive may include epoxy, polyvinyl acetate, polyvinyl alcohol, polyvinyl acrylate, or silicon resin. For example, the UV curing adhesive may include epoxy acrylate, urethane acrylate, polyester acrylate, silicon acrylate, or vinyl ether. The adhesive layer 40a may be formed by a chemical vapor deposition (CVD) process, a spray coating process, or a spin coating process.

The carrier 10 may include a transparent or opaque substrate. For example, if the adhesive layer 40a includes the UV curing adhesive, the carrier 10 may be constructed of a transparent substrate formed of glass or polycarbonate. If the adhesive layer 40a includes the thermosetting adhesive, the carrier layer 10 may be constructed of a transparent substrate or the opaque substrate (e.g., a metal substrate or a silicon substrate).

A release layer 40b may be provided to easily separate the carrier 10 from the substrate 30. In addition, the release layer 40b may also be provided to easily remove the adhesive layer 40a disposed on a sidewall of the device portion 30a. For example, the release layer 40b may include silicon oil or polyethylene. In the present embodiment, the adhesive layer 40a is in contact with the carrier 10 and the release layer 40b is disposed between the adhesive layer 40a and the substrate 30 so as to be in contact with the substrate 30, as illustrated in FIG. 6. However, embodiments of the inventive concepts are not limited thereto. In an embodiment, an additional release layer may further be provided. The additional release layer may be provided between the adhesive layer 40a and the carrier 10 or may be provided to be adjacent to the carrier 10. The adhesive layer 40a and the release layer 40b may be defined as an intermediate layer 40. Hereinafter, for the purpose of ease and convenience in explanation, the intermediate layer 40 between the device portion 30a and the carrier 10 may be defined as a first portion P1 of the intermediate layer 40, and the intermediate layer 40 between the edge portion 30b and the carrier 10 may be defined as a second portion P2 of the intermediate layer 40.

According to an embodiment of the inventive concepts, a thickness difference may occur between the edge portion 30b and the device portion 30a. In other words, the device portion 30a may protrude from the edge portion 30b toward the carrier 10 by a first thickness T1. For example, the first thickness T1 may be about 350 μm. The edge portion 30b may include a bevel region or an inclined sidewall. Since the thickness difference occurs between the device portion 30a and the edge portion 30b, the second portion P2 of the intermediate layer 40 may not completely fill a space between the edge portion 30b and the carrier 10 when the substrate 30 is bonded to the carrier 10 with the intermediate layer 40 interposed there between. In other words, as shown in FIG. 6, an outer sidewall of the second portion P2 may have a profile curved toward the first portion P1 of the intermediate layer 40.

The carrier 10 bonded to the substrate 30 is loaded within the substrate treating apparatus 200A, and then a substrate treating process is performed. In an embodiment, the substrate treating process is performed using the substrate treating apparatus 200A of FIG. 5. Hereinafter, a substrate treating method according to an embodiment will be described with reference to FIGS. 8 to 14.

As described with reference to FIG. 5A, the carrier 10 loaded into the substrate treating apparatus 200A may be safely loaded on the spin chuck 112 of the loading region R1. According to an embodiment, a protection tape (not shown) may be bonded to a bottom surface of the carrier 10, and the carrier 10 may be safely loaded on the spin chuck 112 with the protection tape interposed there between. The protection tape (not shown) will prevent the carrier 10 from being damaged by rubbing or contact between the spin chuck 112 and the carrier 10 and will securely hold the carrier 10 in place on the spin chuck 112.

The carrier 10 loaded on the spin chuck 112 of the loading region R1 is moved into the first grinding region R2 by the rotation of the index table 150, and then the rough grinding process is performed to roughly grind the back side of the substrate 30. According to an embodiment of the inventive concepts, the rough grinding process may be performed in two steps. In other words, performing the rough grinding process may include performing a first rough grinding process and performing a second rough grinding process. The first rough grinding process and the second rough grinding process may be sequentially performed with an interval there between or may be continuously performed. Hereinafter, these will be described in more detail.

Referring to FIGS. 8 and 9, the first rough grinding process is performed on the substrate 30 (S10). In other words, the grinding head 122 of the first grinding region R2 is brought into contact with the substrate 30 to grind the back side of the substrate 30 to thin the device portion 30a. The device portion 30a thinned by the first rough grinding process will have a second thickness T2. The second thickness T2 is less than the first thickness T1 of FIG. 6. For example, the second thickness T2 may be about 300 μm. During this stage of the process, the edge portion 30b is removed. Since the edge portion 30b is removed, the second portion P2 of the intermediate layer 40 is exposed, and an upper portion of the second portion P2 may also be removed during the first rough grinding process.

Referring to FIGS. 8 and 10, after the first rough grinding process is completed, the high-pressure water is jetted to the second portion P2 of the intermediate layer 40, which is now exposed (S20). According to the inventive concepts, the high-pressure water is jetted by the jet nozzle 138 to the second portion P2 in a diagonal direction. In more detail, the high-pressure water is jetted in a direction from the central portion of the substrate 30 toward the edge of the substrate 30 when viewed from a plan view. The high-pressure water is jetted by the jet nozzle 138 to the second portion P2 of the intermediate layer 40 at a predetermined angle θ inclined to the top surface of the spin chuck 112 when viewed from a cross-sectional view. The high-pressure water may be jetted while rotating the spin chuck 112, so the high-pressure water is uniformly jetted over the entire circumference of a top surface of the second portion P2 of the intermediate layer 40.

The second portion P2 of the intermediate layer 40 is separated from a sidewall of the device portion 30a by the jetted high-pressure water. FIG. 11 illustrates a state where the second portion P2 of the intermediate layer 40 is removed by the jetted high-pressure water. As illustrated in FIG. 11, the high-pressure water is jetted to physically separate the second portion P2 of the intermediate layer 40 from the sidewall of the device portion 30a and from . In other words, the second portion P2 of the intermediate layer 40 is separated from the sidewall of the device portion 30a and from first portion P1 of the intermediate layer 40 by physical force of the high-pressure water applied to the top surface of the second portion P2. The release layer 40b disposed on the sidewall of the device portion 30a assists the second portion P2 to be easily separated from the sidewall of the device portion 30a. According to the inventive concepts, the jet angle θ of the high-pressure water jetted to the second portion P2 of the intermediate layer 40 may be greater than 30 degrees and smaller than 90 degrees. In an embodiment, the jet angle θ of the high-pressure water may range from 45 degrees to 60 degrees. If the jet angle θ of the high-pressure water is smaller than 45 degrees, the second portion P2 may not be easily separated. If the jet angle θ of the high-pressure water is greater than 60 degrees, a portion of the first portion P1 of the intermediate layer 40 may also be removed during the removal of the second portion P2, so an undercut region may be formed in the first portion P1 of the intermediate layer 40. This is because the physical force of the high-pressure water applied to the second portion P2 varies according to the jet angle θ of the high-pressure water. As described with reference to FIG. 4, the jet angle θ of the high-pressure water is controlled by the linear movement of the nozzle body 136 and the jet nozzle 138 along arm 134, the vertical movement of the nozzle body 136 and the jet nozzle 138 along support shaft 132 and the rotation of the jet nozzle 138. about shaft 137.

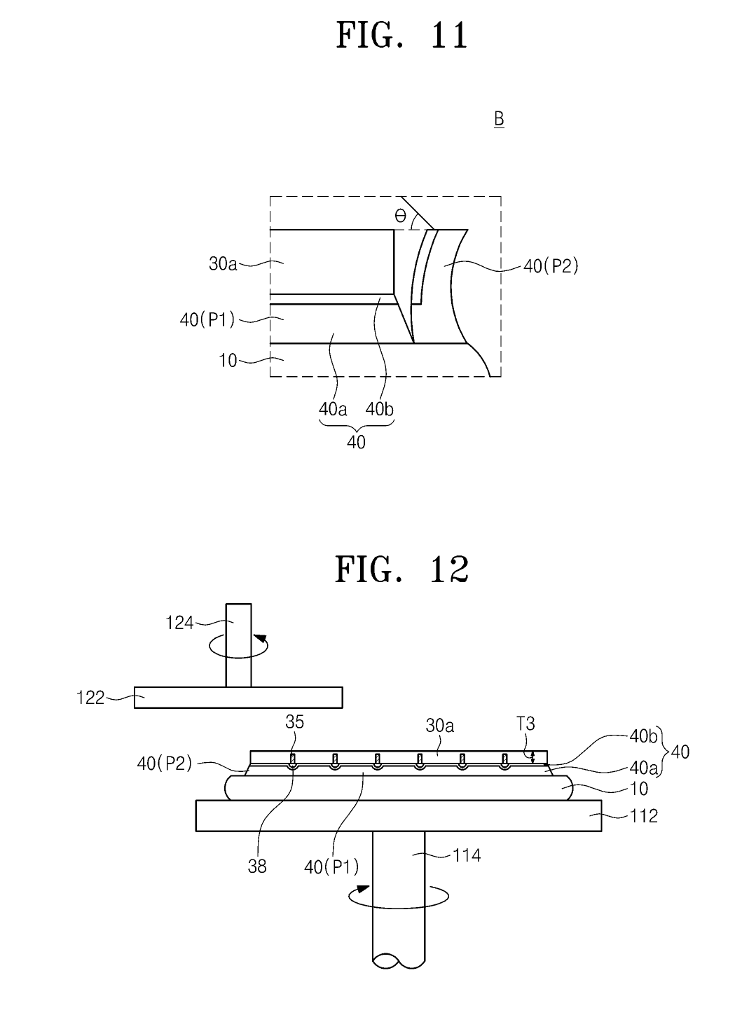

Referring to FIGS. 8 and 12, after the process S20 is completed, the second portion P2 of the intermediate layer 40 is removed. The second portion P2 of the intermediate layer 40 may be partially or completely removed. According to an embodiment, a portion of the second portion P2, which is in contact with the first portion P1 of the intermediate layer 40, may remain, as illustrated in FIG. 12, which shows the outer sidewall of the remaining portion of the second portion P2 as an inclined surface. However, the inventive concepts are not limited thereto. After the removal of the second portion P2 of the intermediate layer 40, the second rough grinding process may be performed on the back side of the device portion 30a (S30). After the second rough grinding process is performed, the device portion 30a will have a third thickness T3. The third thickness T3 may be, for example, about 120 μm.

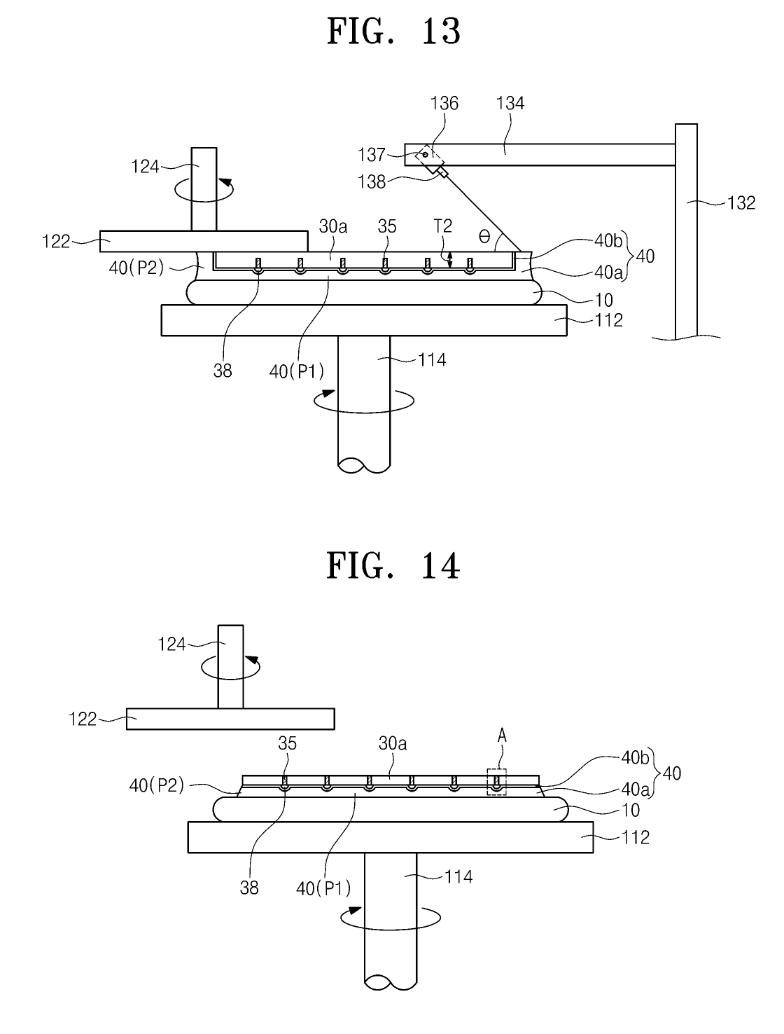

In an alternative operation, the process S20 and the process S30 may be performed at the same time. FIG. 13 illustrates a state where the process S20 and the process S30 are performed at the same time on the same device portion 30a. As illustrated in FIG. 13, after the second portion P2 of the intermediate layer 40 is exposed by the process S10, the high-pressure water is jetted to the exposed second portion P2 of the intermediate layer 40. The back side of the device portion 30a is simultaneously ground by the second rough grinding process (S30) while jetting the high-pressure water by nozzle jet 138. Thus, the process S30 of grinding the device portion 30a and the process S20 of jetting the high-pressure water may be performed at the same time. In other words, in the first grinding region R2, the high-pressure water may be jetted to the second portion P2 of the intermediate layer 40 after the second portion P2 of the intermediate layer 40 is exposed by the rough grinding process. The rough grinding process is continuously performed until the device portion 30a has the third thickness T3, and the second portion P2 of the intermediate layer 40 is removed during the rough grinding process. As a result, the first rough grinding process and the second rough grinding process may be continuously, rather than consecutively, performed. In this case, the first rough grinding process and the second rough grinding process may correspond to a substantially single process.

Referring to FIGS. 8 and 14, after the second rough grinding process (S30) is completed, the carrier 10 is moved into the second grinding region R3. The finishing process (S40) is performed on the substrate 30 in the second grinding region R3. Thus, fine cracks formed in the substrate 30 by the rough grinding process may be removed. After the finishing process (S40) is completed, the carrier layer 10 is moved into the polishing region R4. The polishing process (S50) is performed on the substrate 30 in the polishing region R4. Thus, the back side of the device portion 30a is planarized to expose a bottom surface of the through-via 35.

In an embodiment, if the substrate treating apparatus 200A includes the nozzle member 130 adjacent to the second grinding region R3 or the polishing region R4, the high-pressure water may be jetted after the finishing process S40 or the polishing process S50. Meanwhile, in the present embodiment, the grinding process S10 and S30 to S50 for thinning the substrate 30 and the process S20 of jetting the high-pressure water are performed in the same apparatus. However, the inventive concepts are not limited thereto. The process S20 of jetting the high-pressure water may be performed in an additional apparatus.

As described above, the substrate treating process may be performed through the processes S10 to S50. The substrate treating process according to an embodiment of the inventive concepts may include thinning the substrate 30 by grinding the back side of the substrate 30 coupled to the carrier 10 by the intermediate layer 40, and removing a portion (e.g., the second portion P2) of the intermediate layer 40 by jetting the high-pressure water to the back side of the thinned substrate 30. The second portion P2 of the intermediate layer 40 is removed because it may act as a contamination source in a subsequent process. According to an embodiment of the inventive concepts, the second portion P2 of the intermediate layer 40 is removed by the physical force of the high-pressure water jetted by the jet nozzle 138 using the water-jet method. Thus, the second portion P2 may be effectively removed regardless of whether the intermediate layer 40 is formed from a thermosetting adhesive or an ultraviolet (UV) curing adhesive. In addition, the process of thinning the substrate 30 and the process of removing the portion of the intermediate layer 40 may be performed in the same apparatus, and thus, the processes is simplified to improve productivity of semiconductor devices. Next, subsequent processes of the method for manufacturing the semiconductor device are described.

Referring to FIG. 15, which is an enlarged view diagram of portion ‘A’ of FIG. 14, the carrier 10 is unloaded from the substrate treating apparatus 200A, and then a portion 42 of the device portion substrate 30a is etched-back to expose a portion 31a of a sidewall of the insulating layer 31, as well as a top surface of through-via 35.

Referring to FIG. 16, which is an enlarged view diagram of portion ‘A’ of FIG. 14, a second passivation layer 39 is formed on the back side of the device portion substrate 30a, and a second conductive pad 41 is formed to be in contact with the through-via 35. Even though not shown in the drawings, a redistribution interconnection may be formed to be in contact with the second conductive pad 41.

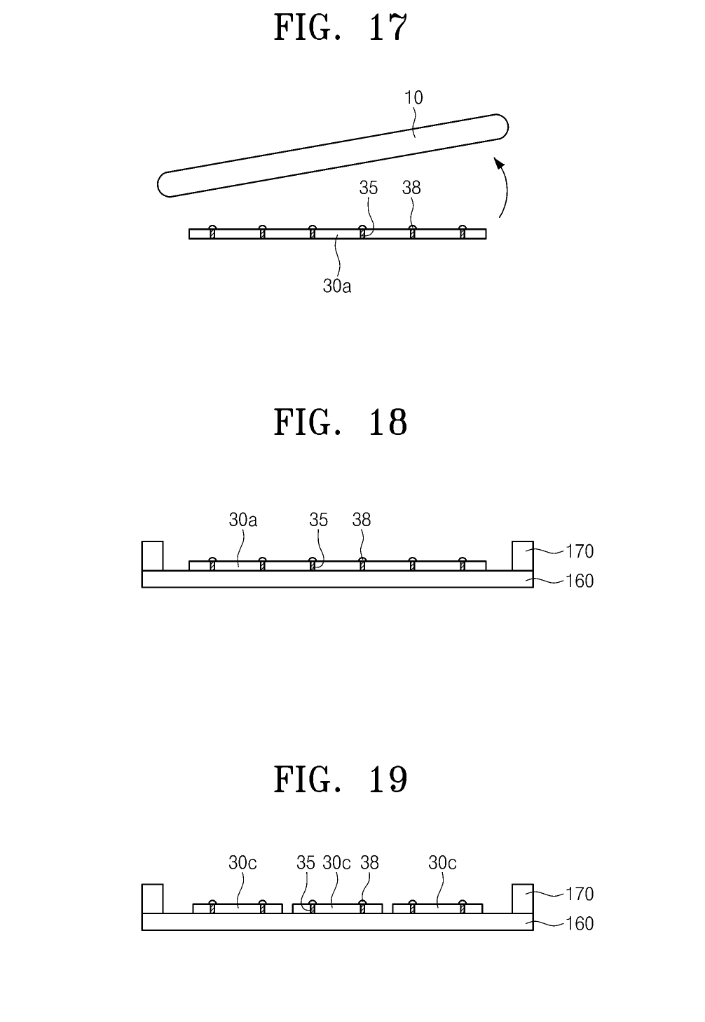

Referring to FIG. 17, the carrier 10 is separated from the device portion substrate 30a. The carrier 10 may be separated by a mechanical method. In an embodiment, the carrier 10 may be separated from the device portion substrate 30a by a suitable apparatus capable of holding an end portion of the carrier 10 and the release layer 40b facilitates separation of the carrier 10 from the device portion substrate 30a. After the separation of the device portion substrate 30a from the carrier 10, the intermediate layer 40 remaining on the substrate 30 is removed. To remove the remaining intermediate layer 40, heat may be applied to the intermediate layer 40 or light may be irradiated to the intermediate layer 40, depending on the material used for the intermediate layer 40, as described above. Alternatively, physical force may be applied to the intermediate layer 40 to remove it from the substrate 30. The thinned device portion substrate 30a including the through-vias 35 may be obtained by the processes described above. The obtained device portion substrate 30a may be packaged by the following processes.

Referring to FIG. 18, the device portion substrate 30a is loaded into a die bonder apparatus including a tape 160 for bonding a chip thereon. As shown, the device portion substrate 30a is also stably fixed by a holder 170.

Referring to FIG. 19, the device portion substrate 30a is sawed to be divided into multiple individual semiconductor chips 30c, each including at least one through-via 35 and bump 38. In an embodiment, the device portion substrate 30a may be cut along a scribe line by a cutting wheel (not shown) so as to be divided into a plurality of semiconductor chips 30c.

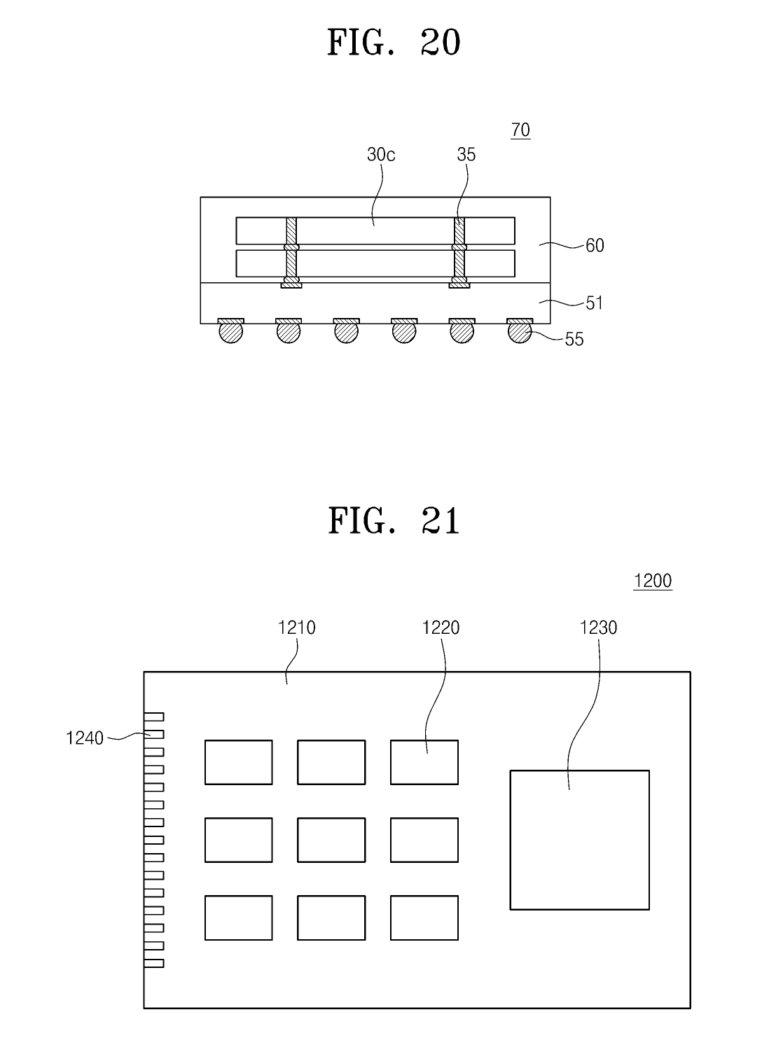

Referring to FIG. 20, a pair of the semiconductor chips 30c divided from the device portion substrate 30a is mounted on a package substrate 51 such as a printed circuit board (PCB). However, it will be understood that a single semiconductor chip 30c or more than 2 semiconductor chips 30c may be mounted on the substrate. In an embodiment, the semiconductor chip 30c is mounted on the package substrate 51 in a face-down manner. Thereafter, a molding process may be performed to form a mold layer 60 covering the semiconductor chip 30c and the package substrate 51. At least one solder ball 55 is bonded to a bottom surface of the package substrate 51. As a result, a semiconductor device 70 may be completed.

As described above, the through-via 35 is formed in the substrate 30.

However, the inventive concepts are not limited thereto. In another embodiment, the through-via 35 may not be formed in the substrate 30. The method for manufacturing the semiconductor device described above may be applied to various kinds of semiconductor devices and a package module including the semiconductor devices.

FIG. 21 is a diagram illustrating an example of a package module including a semiconductor device manufactured according to an embodiment of the inventive concepts. Referring to FIG. 21, a package module 1200 may include a semiconductor integrated circuit chip (e.g., a semiconductor device) 1220 and a semiconductor integrated circuit chip (e.g., a semiconductor device) 1230 packaged by a quad flat package (QFP) technique. In other words, the semiconductor devices 1220 and 1230 implemented with the semiconductor device technique according to the above embodiments of the inventive concepts may be installed on a module substrate 1210 to manufacture the package module 1200. The package module 1200 may be electrically connected to an external electronic device through an external connection terminal 1240 provided on one edge portion of the module substrate 1200.

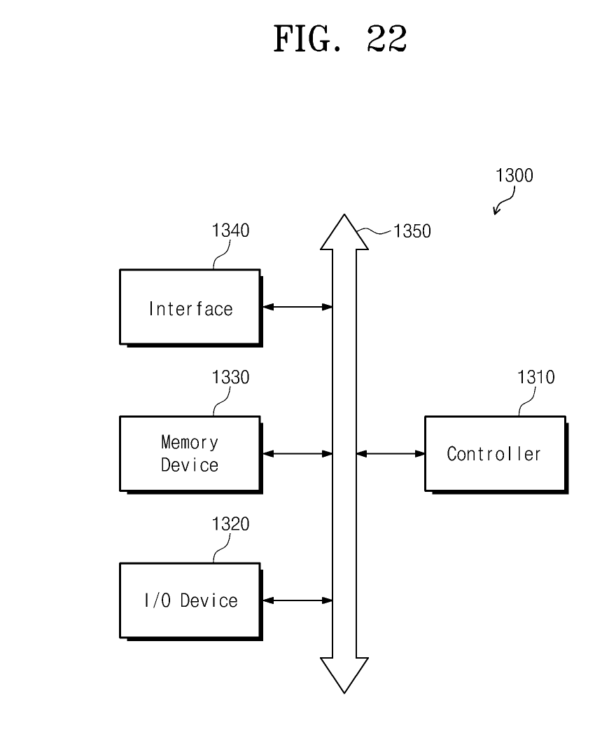

The semiconductor device technique of the aforementioned embodiments may be applied to an electronic system. FIG. 22 is a schematic block diagram illustrating an example of an electronic device including a semiconductor device manufactured according to an embodiment of the inventive concepts. Referring to FIG. 22, an electronic system 1300 may include a controller 1310, an input/output (I/O) device 1320, and a memory device 1330. The controller 1310, the I/O device 1320, and the memory device 1330 may communicate with each other through a data bus 1350. The data bus 1350 may correspond to a path through which electrical signals are transmitted. For example, the controller 1310 may include at least one of a microprocessor, a digital signal processor, a microcontroller, or other logic devices having the same function as any one thereof At least one of the controller 1310 and the memory device 1330 may include a semiconductor device manufactured according to the above embodiments of the inventive concepts. The I/O device 1320 may include a keypad, a keyboard and/or a display device. The memory device 1330 may be a device storing data. The memory device 1330 may store data and/or commands executed by the controller 1310.

The memory device 1330 may include a volatile memory device and/or a non-volatile memory device. In an embodiment, the memory device 1330 may include a flash memory device. For example, the flash memory device manufactured according to the above embodiment of the inventive concepts may be installed in an information processing system such as a mobile device or a desktop computer. The flash memory device may be realized as a solid state disk (SSD). In this case, the electronic system 1300 may stably store massive amounts of data in the memory device 1330. The electronic system 1300 may further include an interface unit .1340 for transmitting electrical data to a communication network and/or for receiving electrical data from a communication network. The interface unit 1340 may operate by wireless or cable.

For example, the interface unit 1340 may include an antenna or a cable/wireless transceiver. Although not shown in the drawings, the electronic system 1300 may further include an application chipset and/or a camera image processor.

The electronic system 1300 may be realized as a mobile system, a personal computer, an industrial computer, or a logic system performing various functions. For example, the mobile system may be any one of a personal digital assistant (PDA), a portable computer, a web tablet, a mobile phone, a wireless phone, a laptop computer, a memory card, a digital music system, or an information transmitting/receiving system. If the electronic system 1300 is a system capable of performing wireless communication, the electronic system 1300 may be used in a communication interface protocol of a communication system such as CDMA, GSM, NADC, E-TDMA, WCDMA, CDMA2000, Wi-Fi, Muni Wi-Fi, Bluetooth, DECT, Wireless USB, Flash-OFDM, IEEE 802.20, GPRS, iBurst, WiBro, WiMAX, WiMAX-Advanced, UMTS-TDD, HSPA, EVDO, LTE-Advanced, or MMDS.

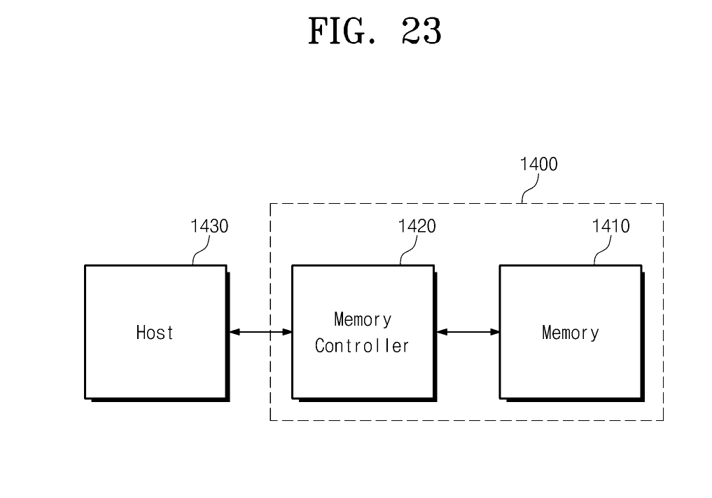

The semiconductor device manufactured according to the aforementioned embodiments of the inventive concepts may be provided in a memory system. FIG. 23 is a schematic block diagram illustrating an example of a memory system including a semiconductor device manufactured according to an embodiment of the inventive concepts. Referring to FIG. 23, a memory system 1400 may include a non-volatile memory device 1410 and a memory controller 1420. The non-volatile memory device 1410 and the memory controller 1420 may store data and/or may read stored data. The non-volatile memory device 1410 may include at least one of non-volatile memory devices manufactured according to the inventive concepts. The memory controller 1420 may control the non-volatile memory device 1410 in response to read/write requests of a host 1430 such that stored data may be read and/or data may be stored.

According to an embodiment of the inventive concepts, the back side of the substrate coupled to the carrier by the intermediate layer is thinned by the grinding process, and the high-pressure water is jetted to the back side of the thinned substrate to remove a portion of the intermediate layer. Since the portion of the intermediate layer is removed by the physical force of the high-pressure water using the water-jet method, it is possible to effectively remove the portion of the intermediate layer. As a result, it is possible to minimize or prevent process defects which may be caused by the intermediate layer in a subsequent process, if the intermediate layer is not properly removed. In addition, the process of thinning the substrate and the process of removing the portion of the intermediate layer may be performed in the same apparatus, and thus, processes may be simplified to improve the productivity of the semiconductor devices.

While the inventive concepts have been described with reference to example embodiments, it will be apparent to those skilled in the art that various changes and modifications may be made without departing from the spirits and scopes of the inventive concepts. Therefore, it should be understood that the above embodiments are not limiting, but illustrative. Thus, the scopes of the inventive concepts are to be determined by the broadest permissible interpretation of the following claims and their equivalents, and shall not be restricted or limited by the foregoing description.

1. A substrate treating apparatus comprising:
a spin chuck configured to support a substrate;
a grinding head disposed over the spin chuck, the grinding head configured to grind the substrate supported by the spin chuck; and
a nozzle member comprising a jet nozzle configured to jet high-pressure water to the substrate supported by the spin chuck,
wherein the jet nozzle overlaps with the substrate to jet the high-pressure water to an edge of the substrate.

2. The substrate treating apparatus of claim 1, wherein the high-pressure water is jetted in a direction from a center of the substrate toward the edge of the substrate when viewed from a plan view, and
wherein the high-pressure water is jetted at an angle inclined to a top surface of the spin chuck when viewed from a cross-sectional view.

3. The substrate treating apparatus of claim 1, wherein the jet nozzle jets the high-pressure water by a water jet method.

4. The substrate treating apparatus of claim 3, wherein a jet pressure of the high-pressure water is in a range of 100 bar to 800 bar.

5. The substrate treating apparatus of claim 1, wherein the nozzle member further comprises:
a support shaft disposed adjacently to the spin chuck;
an arm connected to the support shaft and extending over the substrate; and
a nozzle body coupled to the arm to overlap with the substrate,
wherein the jet nozzle is combined with the nozzle body.

6. The substrate treating apparatus of claim 5, wherein the nozzle body is configured to be linearly movable along the arm in a longitudinal direction of the arm, and
wherein the nozzle body is also configured to be rotatable in a vertical plane on a rotation shaft that is perpendicular to the longitudinal direction.

7. The substrate treating apparatus of claim 5, wherein the arm is configured to be vertically movable along a longitudinal direction of the support shaft.

8. The substrate treating apparatus of claim 5, comprising a plurality of jet nozzles.

9. The substrate treating apparatus of claim 1, wherein the grinding head comprises one of a diamond wheel and a grinding head for polishing.

10. The substrate treating apparatus of claim 1, further comprising:
an index table on which the spin chuck is installed,
wherein the spin chuck includes a plurality of spin chucks including first, second, third and fourth spin chucks installed on the index table at 90 degree intervals, and
wherein the grinding head includes a plurality of grinding heads respectively disposed over the second, third and fourth spin chucks.

11. The substrate treating apparatus of claim 10, wherein the grinding head disposed over the second spin chuck comprises a grinding head configured for performing a rough grinding process of roughly grinding a substrate disposed thereunder,
wherein the grinding head disposed over the third spin chuck comprises a grinding head configured for performing a finishing process of finely grinding a substrate disposed thereunder,
wherein the grinding head disposed over the fourth spin chuck comprises a grinding head configured for performing a polishing process of planarizing a substrate disposed thereunder, and
wherein the nozzle member is provided adjacently to one of the second to fourth spin chucks to jet the high-pressure water to a substrate supported by the one spin chuck.

12. The substrate treating apparatus of claim 11, wherein the nozzle member is provided adjacently to the second spin chuck.

13. The substrate treating apparatus of claim 11, wherein the nozzle member includes a plurality of nozzle members provided adjacently to the second to fourth spin chucks, respectively.

14.-25 (canceled)

26. A substrate treating system comprising:
a substrate treating apparatus including at least one substrate treating station, at least one of the at least one substrate treating stations comprising:
a spin chuck configured for mounting a substrate thereon;
a grinding member disposed over the spin chuck and configured to be brought into contact with the substrate to grind a surface of the substrate;
a nozzle member disposed adjacent to the substrate treating apparatus, including an arm for positioning a nozzle body over a central portion of the spin chuck, the nozzle body including a jet nozzle configured to perform a water jetting process by directing high-pressure water toward an outer edge of the substrate.

27. The substrate treating system of claim 26, wherein the high-pressure water is jetted at an angle inclined to a top surface of the spin chuck when viewed from a cross-sectional view.

28. (canceled)

29. The substrate treating system of claim 26, wherein the nozzle body is configured to be linearly movable along the arm in a longitudinal direction of the arm, and
wherein the nozzle body is also system to be rotatable in a vertical plane on a rotation shaft that is perpendicular to the longitudinal direction.

30. The substrate treating system of claim 26, wherein the nozzle member is configured to vertically move the nozzle body relative to the spin chuck.

31-32. (canceled)

33. The substrate treating system of claim 26, wherein the substrate treating apparatus includes a plurality of substrate treating stations.

34. The substrate treating system of claim 33, wherein a first substrate treating station of the substrate treating apparatus includes a grinding member configured for performing a rough grinding process on the substrate and a second substrate treating station of the substrate treating apparatus includes a grinding member configured for performing a polishing process on the substrate.

35. (canceled)

36. The substrate treating system of claim 34, wherein the nozzle member is disposed adjacent to the first substrate treating station.

37-38. (canceled)
